(19) United States
(12) Patent Application Publication
(10) Pub. No.: US 2025/0364251 A1
(43) Pub. Date: Nov. 27, 2025

(54) METHOD OF PROCESSING WAFER

(71) Applicant: DISCO CORPORATION, Tokyo (JP)

(72) Inventors: Akira Mizutani, Tokyo (JP); Hayato Tanaka, Tokyo (JP)

(21) Appl. No.: 19/189,869

(22) Filed: Apr. 25, 2025

(30) Foreign Application Priority Data
May 22, 2024 (JP) 2024-083034

(51) Int. Cl. H01L 21/268; H01L 21/304

(52) U.S. Cl. CPC H01L 21/268; H01L 21/304

(57) ABSTRACT

A method of processing a wafer that does not leave residue from removal of a chamfered portion. The method includes: a first modified layer forming step of applying a laser beam to an inner side adjacent to a chamfered portion formed on an outer periphery of the first wafer by focusing the laser beam and transmitting through the first wafer to form a ring-shaped modified layer; and a second modified layer forming step of applying the laser beam to a bonded surface of the first and second wafers, by focusing the laser beam and transmitting through the first wafer to form a bonding-force reducing modified layer. In the second modified layer forming step, the bonding-force reducing modified layer is connected with a bottom portion of the ring-shaped modified layer formed in the first modified layer forming step, or a ring-shaped modified layer formed after the second modified layer forming step.

### BACKGROUND OF THE INVENTION

### Field of the Invention

The present invention relates to a wafer processing method to process a bonded wafer in which a first wafer and a second wafer are bonded.

### Description of the Related Art

A wafer on which a plurality of devices, such as ICs and LSIs, are formed on the front surface in a state of being demarcated by division lines, is formed to a predetermined thickness by grinding a rear surface thereof, and is divided into individual device chips by a dicing apparatus and a laser processing apparatus. Each of the divided device chips is used for such electric appliances as a portable telephone and a personal computer.

A chamfered portion is formed on the outer periphery of the wafer, and when the rear surface of the wafer is thinned by grinding, this chamfered portion becomes a sharp knife edge shape. Therefore an operator needs to pay close attention when handling the wafer. Further, the chamfered portion which become a sharp knife edge shape may cause the wafer to crack from the outer periphery in the inward direction, damaging the device. To solve this problem, the applicant of the present invention proposed a technique to form a ring-shaped modified layer in the chamfered portion of the wafer by applying a laser beam to the chamfered portion of the wafer, and removing the chamfered portion thereby (see JP2020-88187A).

### SUMMARY OF THE INVENTION

An available technique to improve the functions of a device is bonding a first wafer and a second wafer, then grinding a rear surface of the first wafer so that the first wafer has a predetermined thickness. A problem of this technique is that by removing the chamfered portion from the first wafer, the residue of the chamfered portion may remain between a side wall of the first wafer and a bonding surface, and this residue becomes a source of contamination.

It is an object of the present invention to provide a method of processing a wafer, in which the residue of the chamfered portion does not remain in the corner between the side wall of the first wafer of a bonded wafer and the bonding surface, in a case of removing the chamfered portion from the first wafer of the bonded wafer.

The present invention provides a following method of processing a wafer to solve the above problem. That is, a method of processing a wafer to process a bonded wafer in which a first wafer and a second wafer are bonded, including:
a first modified layer forming step of applying a laser beam to an inner side adjacent to a chamfered portion formed on an outer periphery of the first wafer, with positioning a focusing point of the laser beam,
transmitting through the first wafer, so as to form a ring-shaped modified layer; and
a second modified layer forming step of applying the laser beam to a bonding surface of the first wafer and the second wafer, with positioning the focusing point of the laser beam, transmitting through the first wafer, so as to form a bonding-force reducing modified layer to reduce the bonding force. In the second modified layer forming step, the bonding-force reducing modified layer is formed to be connected with a bottom portion of the ring-shaped modified layer which is already formed in the first modified layer forming step, or with a bottom portion of a ring-shaped modified layer which is formed after the second modified layer forming step.

It is preferable to further include a fluid supplying step of supplying fluid to weaken the bonding force to the bonding surface in which the first wafer and the second wafer are bonded, from an outer periphery of the bonded wafer, so as to allow the fluid to enter into a region reaching the bonding-force reducing modified layer. The laser beam used in the first modified layer forming step and the laser beam used in the second modified layer forming step may be the same. The fluid supplying step is preferably performed before the second modified layer forming step, after the second modified layer forming step, or at the same time with the second modified layer forming step.

It is preferable to further include a chamfered portion removing step of removing the chamfered portion from the first wafer after the first modified layer forming step and the second modified layer forming step. It is also preferable to further include a grinding step of removing the chamfered portion from the first wafer in a case of thinning the wafer by grinding an upper surface of the first wafer after the first modified layer forming step and the second modified layer forming step.

It is preferable that the first wafer and the second wafer are bonded by the siloxane bond of Si—O—Si, the fluid to weaken the bonding force contains any one of water, vapor and mist, and the bonding force is weakened in the fluid supplying step by Si—O—Si bond changing into Si—OH—OH—Si bond.

The method of processing a wafer of the present invention is a method of processing a wafer to process a bonded wafer in which a first wafer and a second wafer are bonded, including: a first modified layer forming step of applying a laser beam to an inner side adjacent to a chamfered portion formed on an outer periphery of the first wafer, with positioning a focusing point of the laser beam, transmitting through the first wafer, so as to form a ring-shaped modified layer; and a second modified layer forming step of applying the laser beam to a bonding surface of the first wafer and the second wafer, with positioning the focusing point of the laser beam, transmitting through the first wafer, so as to form a bonding-force reducing modified layer to reduce the bonding force. In the second modified layer forming step, the bonding-force reducing modified layer is formed to be connected with a bottom portion of the ring-shaped modified layer which is already formed in the first modified layer forming step, or with a bottom portion of a ring-shaped modified layer which is formed after the second modified layer forming step. Therefore in a case of removing the chamfered portion from the first wafer of the bonded wafer, residue of the chamfered portion does not remain in the corner between the side wall of the first wafer and the bonding surface.

### BRIEF DESCRIPTION OF THE DRAWINGS

FIG. 1A is a perspective view of a bonded wafer, and FIG. 1B is a partial cross-sectional view of the wafer illustrated in FIG. 1A;

FIG. 2A is a perspective view illustrating a first modified layer forming step, FIG. 2B is a partial cross-sectional view of the bonded wafer in which a ring-shaped modified layer is formed on a first wafer, and FIG. 2C is a partial cross-sectional view of the bonded wafer in which a plurality of ring-shaped modified layers are formed at different positions in the diameter direction;

FIG. 3 is a plan view of a wafer in which a modified layer is radially formed extending outward from the ring-shaped modified layer in the diameter direction;

FIG. 4A is a perspective view illustrating a second modified layer forming step, FIG. 4B is a partial cross-sectional view of the bonded wafer in which a bonding-force reducing modified layer is formed on the bonding surface between the first wafer and the second wafer, and FIG. 4C is a partial cross-sectional view of the bonded wafer in which the second modified layer forming step was performed before the first modified layer forming step;

FIG. 5A is a perspective view illustrating a fluid supplying step, FIG. 5B is a side view illustrating the fluid supplying step, and FIG. 5C is a perspective view illustrating a state where the fluid supplying step is being performed at the same time with the second modified layer forming step;

FIG. 6 is a diagram illustrating a chamfered portion removing step; and

FIG. 7A is a perspective view illustrating a state when the grinding step is started, FIG. 7B is a perspective view illustrating a state when the grinding step is ended, and FIG. 7C is a perspective view of the bonded wafer after the chamfered portion of the first wafer is removed in the grinding step.

### DESCRIPTION OF THE PREFERRED EMBODIMENTS

Preferred embodiments of the method of processing a wafer according to the present invention will be described with reference to the drawings.

### Bonded Wafer 2

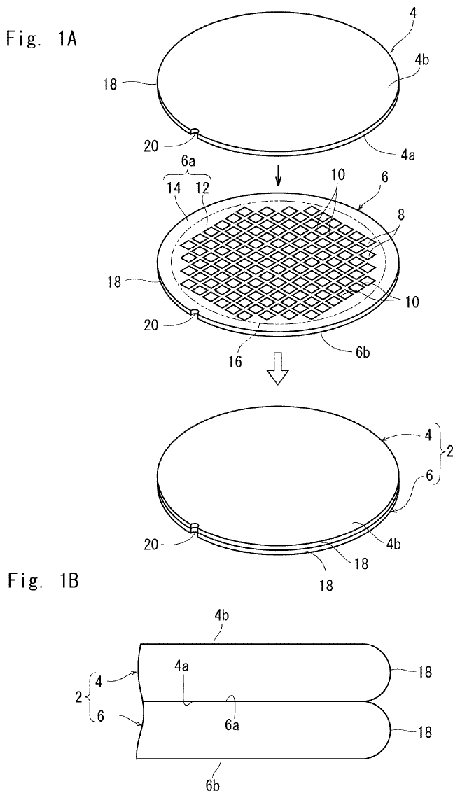

FIGS. 1A and 1B indicate a disk-shaped bonded wafer 2 to be processed by the method according to the present invention. The bonded wafer 2 is an integration of a first wafer 4 and a second wafer 6 which are laminated.

The first wafer 4 and the second wafer 6 are formed of silicon (Si), and are formed to have about a 200 mm diameter and about a 700 μm thickness, for example. As illustrated in FIG. 1A, a front surface 6a of the second wafer 6 includes a device region 12, where a plurality of devices 8 (e.g. ICs, LSIs) are demarcated by lattice-like division lines 10, and an outer peripheral surplus region 14 which surrounds the device region 12. In FIG. 1A, a ring-shaped boundary 16 between the device region 12 and the outer peripheral surplus region 14 is indicated by a two-dot chain line for convenience, but no line actually exists to indicate the boundary 16. A front surface 4a of the first wafer 4 also has the same configuration as the front surface 6a of the second wafer 6, although this is not illustrated. On each of the outer periphery of the first wafer 4 and the second wafer 6, a chamfered portion 18 having a curved surface is formed, and a notch 20 is formed to indicate crystal orientation.

To form the bonded wafer 2, the device region 12 of the first wafer 4 and the device region 12 of the second wafer 6 are bonded. Here the first wafer 4 and the second wafer 6 are bonded in a state where the notch 20 of the first wafer 4 and the notch 20 of the second wafer 6 are aligned, so that the crystal orientation of the first wafer 4 and the crystal orientation of the second wafer 6 match. Once the first wafer 4 and the second wafer 6 are bonded, it is preferable to perform thermal treatment to tightly adhere the first wafer 4 and the second wafer 6 to each other by a siloxane bond. The siloxane bond is an Si—O—Si bond in which silicon (Si) and oxygen (O) are alternately bonded, whereby a strongly bonded state is maintained even at high temperatures.

### First Modified Layer Forming Step

In the present embodiment, a first modified layer forming step is performed first, where a laser beam is applied to an inner side adjacent to the chamfered portion 18 formed on an outer periphery of the first wafer 4, with positioning a focusing point of the laser beam, transmitting through the first wafer 4, so as to form a ring-shaped modified layer.

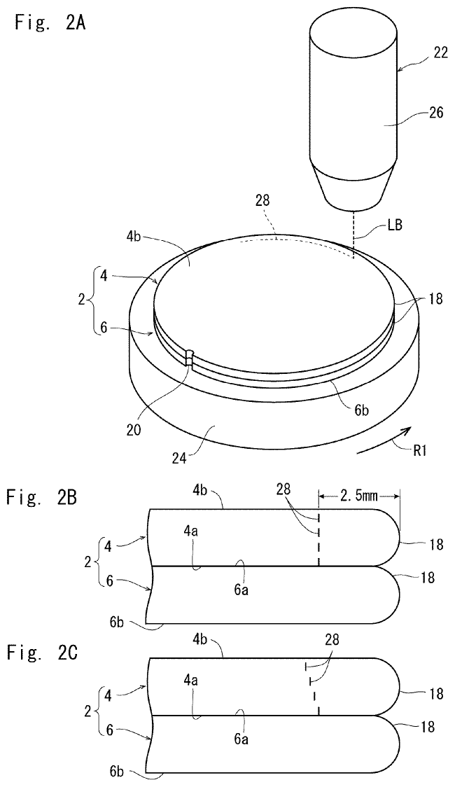

The first modified layer forming step can be performed using a laser processing apparatus 22 illustrated in FIG. 2A, for example. The laser processing apparatus 22 includes a chuck table 24 which suction-holds a wafer, an oscillator (not illustrated) which oscillates a pulsed laser beam LB having a wavelength to be transmissive to the bonded wafer 2, and a condenser 26 which focuses the laser beam LB oscillated by the oscillator and applies the laser beam LB onto the first wafer 4.

In the first modified layer forming step, the bonded wafer 2 is suction-held onto the upper surface of the chuck table 24. In this case, the bonded wafer 2 is placed on the upper surface of the chuck table 24 in a state where the rotation center of the chuck table 24 and the center of the bonded wafer 2 are aligned. Here the first wafer 4, of which chamfered portion 18 is to be removed, is disposed on the upper side. The suction force is generated on the upper surface of the chuck table 24 by suction means (not illustrated), and the rear surface 6b side of the second wafer 6 is suction-held onto the upper surface of the chuck table 24.

After the bonded wafer 2 is suction-held on the chuck table 24, a processing line to apply the laser beam LB is set. In this case, an image of the first wafer 4 is captured from above using an imaging unit (not illustrated) of the laser processing apparatus 22, and the outer periphery and the center position of the first wafer 4 are detected based on the image of the first wafer 4 captured by the imaging unit. Then based on the detected outer periphery and the center position of the first wafer 4, a ring-shaped line located on the inner side adjacent to the chamfered portion 18, which is formed on the outer periphery of the first wafer 4, is set as the processing line. For example, in a case where the chamfered portion 18 is formed in a ring-shaped region about 2 mm wide from the outer periphery of the first wafer 4, a ring-shaped line located 2.5 mm on the inner side from the outer periphery of the first wafer 4 is set as the processing line.

Once the processing line to apply the laser beam LB is set, the focusing point of the laser beam LB is positioned at a predetermined position on the processing line. In this case, a height of the rear surface 4b of the first wager 4 (that is, a height of the upper surface of the bonded wafer 2) is detected by a height detecting unit (not illustrated) of the laser processing apparatus 22. Then using the detected height of the rear surface 4b as a reference, the focusing point of the laser beam LB is positioned as the predetermined position (inside the outer peripheral surplus region 14) on the processing line in the inner portion of the first wafer 4, transmitting through the first wafer 4.

Once the focusing point of the laser beam LB is positioned at the predetermined position, the laser beam LB, having a wavelength that has transmissivity to the bonded wafer 2, is applied to the first wafer 4, so as to form the ring-shaped modified layer 28 along the chamfered portion 18. In other words, the laser beam LB is applied to the first wafer 4 while rotating the chuck table 24 in the direction indicated by the arrow R1 in FIG. 2A, thereby the ring-shaped modified layer 28 is formed throughout the entire circumference of the ring-shaped processing line.

Once one (one circle) of the ring-shaped modified layers 28 is formed, the height position of the focusing point of the laser beam LB is changed to a shallower position, and the laser beam LB is applied to the first wafer 4 in the same manner. By repeating the change of the height position of the focusing point and applying the laser beam LB like this, a plurality of ring-shaped modified layers 28 are formed in the vertical direction with intervals, as illustrated in FIG. 2B. The modified layers 28 which are adjacent to each other in the vertical direction can be connected by cracks (not illustrated) extending from the modified layers 28.

After one (one cycle) of the ring-shaped modified layer 28 is formed, a plurality of ring-shaped modified layers 28, having different depths, may be formed at different positions in the diameter direction, as illustrated in FIG. 2C. In other words, a plurality of ring-shaped modified layers 28 may be formed at different positions in the diameter direction, so that the plurality of ring-shaped modified layers as a whole are inclined outward in the diameter direction from the rear surface 4b (upper surface) to the front surface 4a (lower surface). In this case, the previously formed modified layer 28 does not interrupt the focusing of the laser beam LB to form the next modified layer 28, hence the ring-shaped modified layers 28 can be formed from a shallower position (a position closer to the rear surface 4b of the first wafer 4).

The first modified layer forming step can be performed under the following processing conditions, for example. The following defocus is a moving distance when the condenser 26 is moved toward the bonded wafer 2 from the state where the focusing point of the laser beam LB is positioned on the rear surface 4b (exposure surface) of the first wafer 4.
Wavelength of laser beam: 1342 nm
Repetition frequency: 80 kHz
Feeding speed of focusing point: 60 rpm
Average output: 2 W
Defocus: 700 μm, 500 μm, 300 μm, 150 μm

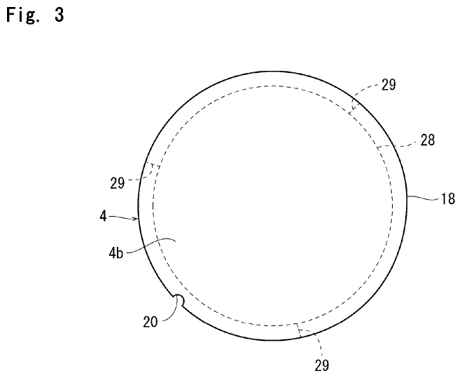

In the first modified layer forming step, a modified layer 29, which radially extends from the ring-shaped modified layer 28, may be additionally formed (see FIG. 3). In other words, a plurality of (three in this embodiment) of linear modified layers 29, which extend outward from the ring-shaped modified layer 28 to the outer periphery of the first wafer 4 in the diameter direction, may be formed radially with equal intervals in the circumferential direction inside the first wafer 4. It is preferable that a plurality of layers of the modified layer 29 are formed radially, just like the ring-shaped modified layers 28, with intervals in the vertical direction. By forming the modified layers 29 radially like this, the chamfered portion 18 can be divided into smaller pieces and easily removed in the chamfered portion removing step, which will be described later.

### Second Modified Layer Forming Step

After performing the first modified layer forming step, a second modified layer forming step is performed, where a laser beam is applied to a bonding surface of the first wafer 4 and the second wafer 6, with positioning a focusing point of the laser beam, transmitting through the first wafer 4, so as to form a bonding-force reducing modified layer to reduce the bonding force.

The second modified layer forming step can be performed using the laser processing apparatus 22 mentioned above. In other words, the same laser beam LB may be used in the first and second modified layer forming steps. Specifically, the wavelength, repetition frequency, feed speed of the focusing point, and average output of the laser beam LB may be the same for the first and second modified layer forming steps.

In the second modified layer forming step, the focusing point of the laser beam LB is positioned at a predetermined position, while continuing the suction-holding of the bonded wafer 2 onto the chuck table 24. Specifically, the focusing point of the laser beam LB is positioned on the outer periphery side of the bonding surface of the first wafer 4 and the second wafer 6, transmitting through the first wafer 4.

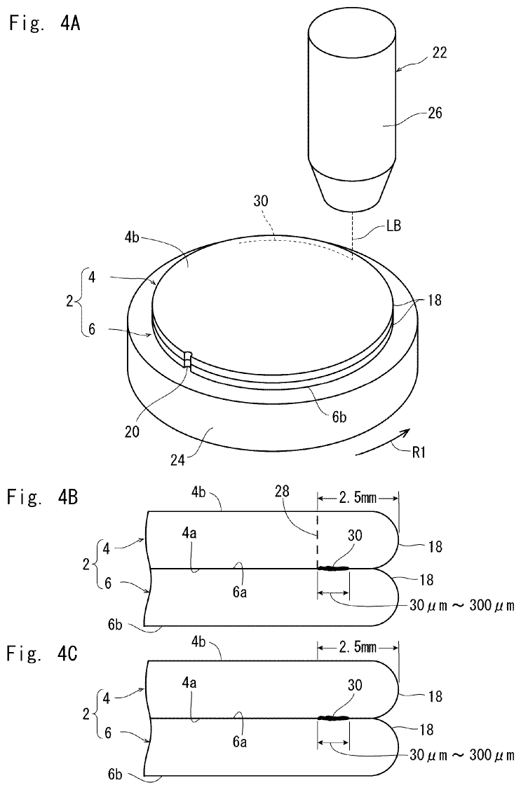

Once the focusing point of the laser beam LB is positioned at the predetermined position, the laser beam LB having a wavelength, that has transmissivity to the bonded wafer 2, is applied to the bonding surface, so as to form a ring-shaped bonding-force reducing modified layer 30 to reduce the bonding force of the bonded wafer 2. In other words, the laser beam LB is applied to the bonding surface of the bonded wafer 2, while rotating the chuck table 24 in the direction indicated by the arrow R1 in FIG. 4A, thereby the ring-shaped bonding-force reducing modified layer 30 is formed.

Once one (one cycle) of the bonding-force reducing modified layers 30 is formed, the position of the focusing point of the laser beam LB in the diameter direction is changed, and the laser beam LB is applied to the bonding surface in the same manner as above. By repeating the change of the position of the focusing point in the diameter direction and applying the laser beam LB like this, a plurality of ring-shaped bonding-force reducing modified layers 30 are formed in a predetermined distance range (e.g. about 30 μm to 300 μm) outward from the lower end of the ring-shaped modified layer 28 in the diameter direction (see FIG. 4B). In other words, in the second modified layer forming step, the bonding-force reducing modified layer 30 is formed so as to be connected with the bottom portion of the ring-shaped modified layer 28, which has already been formed in the first modified layer forming step. The bonding-force reducing modified layers 30, which are adjacent to each other in the diameter direction, can be connected by cracking (not illustrated), extending from the bonding-force reducing modified layers 30. Therefore the bonding-force reducing modified layers 30 may be formed with intervals in the diameter direction.

The second modified layer forming step can be performed under the following processing conditions, for example.
Wavelength of laser beam: 1342 nm
Repetition frequency: 80 kHz
Feeding speed of focusing point: 60 rpm
Average output: 2 W
Defocus: 700 μm±30 μm

In the present embodiment, the second modified layer forming step is performed after performing the first modified layer forming step, but the second modified layer forming step may be performed before performing the first modified layer forming step. In other words, the bonding-force reducing modified layer 30 may be formed before forming the ring-shaped modified layer 28 (see FIG. 4C). In this case, the bonding-force reducing modified layer 30 is formed so as to be connected with the bottom portion of the ring-shaped modified layer 28 formed after the second modified layer forming step.

### Fluid Supplying Step

After performing the second modified layer forming step, a fluid supplying step is performed, where fluid to weaken the bonding force is supplied to the bonding surface in which the first wafer 4 and the second wafer 6 are bonded, from an outer periphery of the bonded wafer 2, so as to allow the fluid to enter into a region reaching the bonding-force reducing modified layer 30.

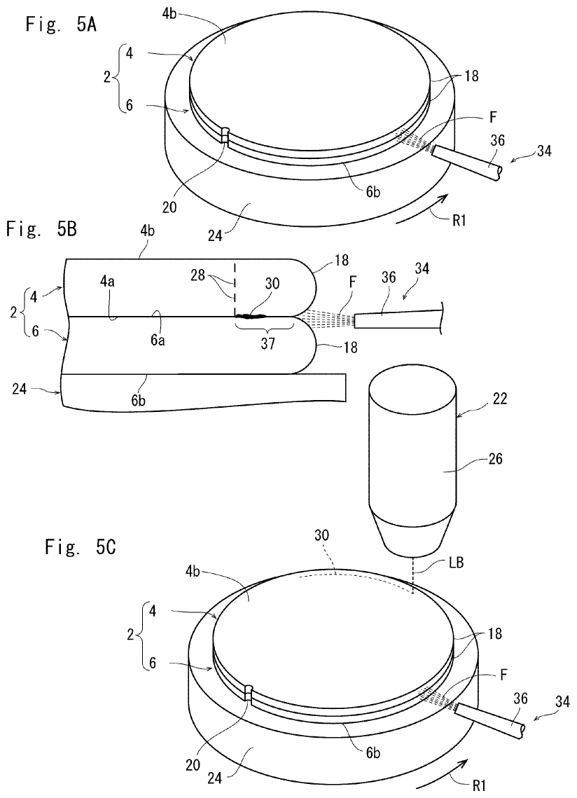

The fluid supplying step can be performed using a fluid supplying apparatus 34 illustrated in FIG. 5A, for example. The fluid supplying apparatus 34 includes a nozzle 36 which is configured to be movable, and a fluid supplying source (not illustrated) which supplies fluid F to the nozzle 36. The fluid supplying apparatus 34 may be attached to the laser processing apparatus 22. In the present embodiment, an example where the fluid supplying apparatus 34 is attached to the laser processing apparatus 22 will be described.

In the fluid supplying step, the chuck table 24 is moved close to the nozzle 36 of the fluid supplying apparatus 34. Then the tip of the nozzle 36 is positioned on a side of the bonded wafer 2. Then the chuck table 24 is rotated in a direction indicated by the arrow R1 in FIG. 5A. Then fluid F is supplied from the fluid supplying source to the nozzle 36. Then as illustrated in FIGS. 5A and 5B, the fluid F (e.g. pure water), to weaken the bonding force, is supplied to the bonding surface of the bonded wafer 2 through the nozzle 36. Thereby the fluid F is allowed to enter from the outer periphery of the bonded wafer 2 into the region reaching the bonding-force reducing modified layer 30. The form of the fluid F is not limited to liquid, and may be steam or mist.

As mentioned above, the bonding surface of the bonded wafer 2 is bonded by the siloxane bond (Si—O—Si bond). If fluid F is supplied from the side of the bonded wafer 2 toward the bonding surface of the bonded wafer 2, the fluid F gradually enters from the outer periphery of the bonded wafer 2 toward the bonded surface, and the region into which the fluid F enters changes to an Si—OH—OH—Si bond. As a result, the bonding force of the region where the fluid F entered is weakened, and a ring-shaped bonding-force weakened region 37 is formed on the outer periphery side of the bonding surface.

In the present embodiment, the fluid supplying step is performed after performing the second modified layer forming step, but the fluid supplying step may be performed before performing the second modified layer forming step. Further, as illustrated in FIG. 5C, the second modified layer forming step and the fluid supplying step may be performed simultaneously.

### Chamfered Portion Removing Step

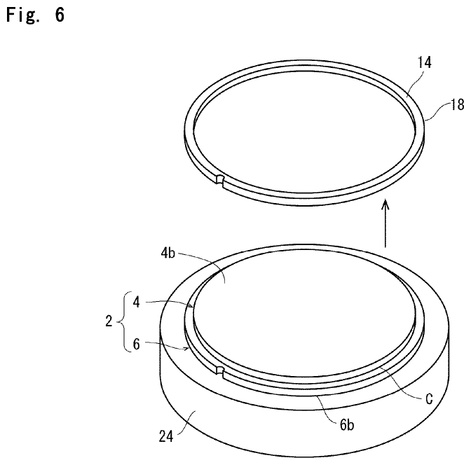

After performing the fluid supplying step, a chamfered portion removing step of removing the chamfered portion 18 from the first wafer 4 is performed (see FIG. 6). In a case of omitting the fluid supplying step, the chamfered portion removing step is performed after performing the first modified layer forming step and the second modified layer forming step.

In the chamfered portion removing step, an external force is applied to the chamfered portion 18 of the first wafer 4 using appropriate external force applying means, so as to remove the chamfered portion 18 from the first wafer 4. For example, the external force can be applied to the chamfered portion 18 by ejecting high pressure fluid, such as water or air, from the outer periphery side of the bonded wafer 2. In the example in FIG. 6, the chamfer portion 18 is removed from the first wafer 4 while maintaining the ring shape, but the chamfered portion 18 may be removed by dividing it into a plurality of pieces.

As mentioned above, in the present embodiment, the ring-shaped modified layer 28 and the bonding-force reducing modified layer 30 are formed in the first and second modified layer forming steps, hence the chamfered portion 18 can be completely removed from the first wafer 4 with the ring-shaped modified layer 28 and the bonding-force reducing modified layer 30 as an interface. Therefore when the chamfered portion 18 is removed from the first wafer 4, no residue of the chamfered portion 18 remains at the corner C between the side wall of the first wafer 4 and the bonding surface. The chamfered portion 18 can be removed even more efficiently in a case where the bonding-force weakening region 37 is formed on the outer periphery of the bonding surface by performing the fluid supplying step.

### Grinding Step

Instead of the chamfered portion removing step mentioned above, a grinding step of removing the chamfered portion 18 from the first wafer 4 may be performed in a case of thinning the first wafer 4 by grinding an upper surface of the first wafer 4 after performing the first modified layer forming step and the second modified layer forming step, or after performing the fluid supplying step.

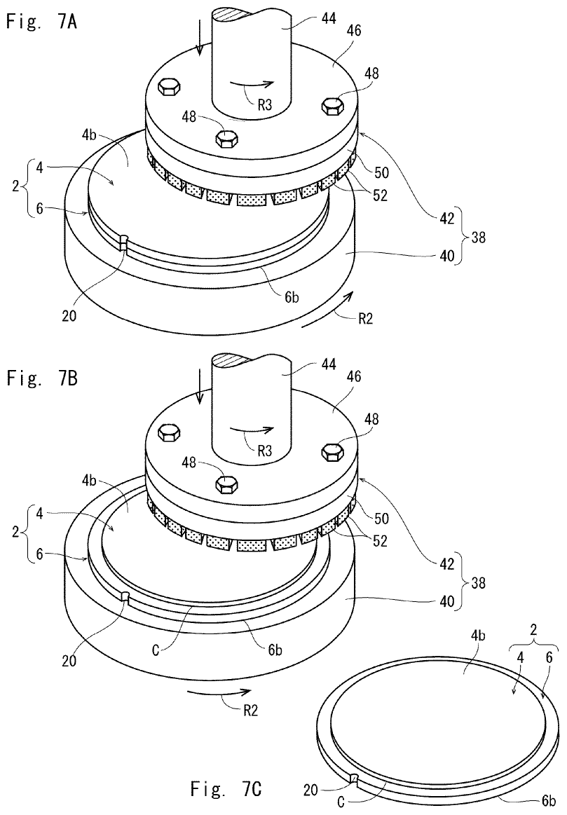

The grinding step can be performed using a grinding apparatus 38 illustrated in FIGS. 7A and 7B, for example. The grinding apparatus 38 includes a chuck table 40 which suction-holds the bonded wafer 2, and a grinding unit 42 which grinds the bonded wafer 2 that is suction-held by the chuck table 40. The grinding unit 42 includes a spindle 44 which extends in the vertical direction, and a disk-shaped wheel mount 46 which is fixed at the lower end of the spindle 44. On the lower surface of the wheel mount 46, an annular-shaped grinding wheel 50 is fastened by a bolt 48. On the outer periphery of the lower surface of the grinding wheel 50, a plurality of grinding stones 52 are fixed in an annular shape with intervals in the circumferential direction.

In the grinding step, the rear surface 4b of the first wafer 4 is turned upward, and the rear surface 6b side of the second wafer 6 is suction-held onto the upper surface of the chuck table 40. Then the chuck table 40 is rotated at a predetermined rotation speed (e.g. 300 rpm) in the direction indicated by the arrow R2. The spindle 44 is also rotated at a predetermined rotation speed (e.g. 6000 rpm) in the direction indicated by the arrow R3. Then the spindle 44 is lowered so that the grinding stones 52 contact with the rear surface 4b of the first wafer 4, and grinding water is supplied to the portion where the grinding stones 52 contact with the rear surface 4b of the first wafer 4. Then the spindle 44 is lowered at a predetermined grinding feed speed (e.g. 0.1 μm/s). Thereby the rear surface 4b of the first wafer 4 is ground as illustrated in FIGS. 7B and 7C, so that the first wafer 4 is formed to a predetermined thickness. By the downward force that acts from the grinding unit 42 onto the bonded wafer 2 during grinding and the force of the grinding stones moving outward, the chamfered portion 18 can be completely removed from the first wafer 4 with the ring-shaped modified layer 28 and the bonding-force reducing modified layer 30 as the interface.

As described above, in the present embodiment, the ring-shaped modified layer 28 and the bonding-force reducing modified layer 30 are formed in the first and second modified layer forming steps, hence the chamfered portion 18 can be completely removed from the first wafer 4 with the ring-shaped modified layer 28 and the bonding-force reducing modified layer 30 as the interface. Therefore when the chamfered portion 18 is removed from the first wafer 4, and no residue of the chamfered portion 18 remains at the corner C between the side wall of the first wafer 4 and the bonding surface.

### REFERENCE SIGNS LIST

2 Bonded wafer
4 First wafer
6 Second wafer
18 Chamfered portion
28 Ring-shaped modified layer
30 Bonding-force reducing modified layer
F Fluid

What is claimed is:

1. A method of processing a wafer to process a bonded wafer in which a first wafer and a second wafer are bonded, comprising:
a first modified layer forming step of applying a laser beam to an inner side adjacent to a chamfered portion formed on an outer periphery of the first wafer, with positioning a focusing point of the laser beam, transmitting through the first wafer, so as to form a ring-shaped modified layer; and
a second modified layer forming step of applying the laser beam to a bonding surface of the first wafer and the second wafer, with positioning the focusing point of the laser beam, transmitting through the first wafer, so as to form a bonding-force reducing modified layer to reduce the bonding force, wherein
in the second modified layer forming step, the bonding-force reducing modified layer is formed to be connected with a bottom portion of the ring-shaped modified layer which is already formed in the first modified layer forming step, or a ring-shaped modified layer which is formed after the second modified layer forming step.

2. The method of processing a wafer of claim 1, further including a fluid supplying step of supplying fluid to weaken the bonding force to the bonding surface in which the first wafer and the second wafer are bonded, from an outer periphery of the bonded wafer, so as to allow the fluid to enter into a region reaching the bonding-force reducing modified layer.

3. The method of processing a wafer of claim 1, wherein the laser beam used in the first modified layer forming step and the laser beam used in the second modified layer forming step are the same.

4. The method of processing a wafer of claim 2, wherein
the fluid supplying step is performed before the second modified layer forming step, after the second modified layer forming step, or at the same time with the second modified layer forming step.

5. The method of processing a wafer of claim 1, further comprising
a chamfered portion removing step of removing the chamfered portion from the first wafer after the first modified layer forming step and the second modified layer forming step.

6. The method of processing a wafer of claim 1, further comprising
a grinding step of removing the chamfered portion from the first wafer in a case of thinning the wafer by grinding an upper surface of the first wafer after performing the first modified layer forming step and the second modified layer forming step.

7. The method of processing a wafer of claim 2, wherein
the first wafer and the second wafer are bonded by siloxane bond of Si—O—Si,
the fluid to weaken the bonding force contains any one of water, vapor and mist, and
the bonding force is weakened in the fluid supplying step by the Si—O—Si bond changing into Si—OH—OH—Si bond.
